(19) United States
(12) Patent Application Publication
(10) Pub. No.: US 2025/0126879 A1
(43) Pub. Date: Apr. 17, 2025

(54) ELECTROSTATIC DISCHARGE PROTECTION DEVICES WITH LOW CAPACITANCE

(71) Applicant: Texas Instruments Incorporated, Dallas, TX (US)

(72) Inventors: Kartikey Mayurkumar Thakar, Rajkot (IN); Sunglyong Kim, Allen, TX (US); Gang Xue, San Jose, CA (US); Tian Ping Lv, Yibin (CN)

(21) Appl. No.: 18/484,655

(22) Filed: Oct. 11, 2023

(51) Int. Cl. H01L 27/08; H01L 21/8222

(52) U.S. Cl. CPC H10D 84/221; H10D 84/0112; H10D 84/038

(57) ABSTRACT

Diodes for ESD protection devices are described. The diodes have low capacitance. In an example, a semiconductor device includes a substrate, an n-type epitaxial layer on the n-type substrate in a first region of the n-type substrate, and a p-type epitaxial layer on the n-type epitaxial layer with an interface between the n-type and p-type epitaxial layers. The p-type epitaxial layer has a first concentration of p-type dopants throughout the p-type epitaxial layer. Also, the semiconductor device includes a p-type dopant distribution straddling across the interface, the p-type dopant distribution having a first peak concentration of p-type dopants greater than the first concentration, and an n-type dopant distribution straddling across the interface, the n-type dopant distribution having a second peak concentration of n-type dopants. The second peak concentration is substantially same as the first peak concentration.

### TECHNICAL FIELD

The present disclosure relates to the field of semiconductor devices, and more particularly to low capacitance electrostatic discharge (ESD) diodes.

### BACKGROUND

Integrated circuits (ICs) can be subject to ESD events, which typically occur when the ICs are brought in contact with or close to another object. ESD protection devices may be coupled with ICs to provide current paths during ESD events to protect the ICs. It would be desirable for the ESD protection devices to be able to safely dissipate high current without incurring damage. During normal operations of the ICs, the ESD protection devices are inactive so as not to interfere with the normal operations. Although the ESD protection devices are inactive (e.g., a diode under a reverse bias condition), their presence tends to increase parasitic capacitance for the ICs. It would be desirable for the ESD protection devices to have low capacitance.

### SUMMARY

The present disclosure describes ESD protection devices that include diodes with low capacitance. This summary is not an extensive overview of the disclosure. Rather, the primary purpose of the summary is to present some concepts of the disclosure in a simplified form as a prelude to a more detailed description that is presented later.

In some examples, a semiconductor device includes an n-type substrate; an n-type epitaxial layer on the n-type substrate in a first region of the n-type substrate; a p-type epitaxial layer on the n-type epitaxial layer with an interface between the n-type and p-type epitaxial layers, the p-type epitaxial layer having a first concentration of p-type dopants throughout the p-type epitaxial layer; a p-type dopant distribution straddling across the interface, the p-type dopant distribution having a first peak concentration of p-type dopants greater than the first concentration; and an n-type dopant distribution straddling across the interface, the n-type dopant distribution having a second peak concentration of n-type dopants, the second peak concentration is substantially same as the first peak concentration.

In some examples, a method includes growing an n-type epitaxial layer on an n-type substrate. The method also includes implanting p-type dopants in a second region of the n-type epitaxial layer. The method also includes implanting n-type dopants in a first region of the n-type epitaxial layer different than the second region. The method also includes growing a p-type epitaxial layer over the n-type substrate such that an interface forms between the n-type and p-type epitaxial layers in the first region, where: the p-type epitaxial layer in the first region includes a first concentration of p-type dopants throughout the p-type epitaxial layer; a p-type dopant distribution forms across the interface as a result of growing the p-type epitaxial layer, the p-type dopant distribution having a first peak concentration of p-type dopants greater than the first concentration; and an n-type dopant distribution forms across the interface as a result of implanting n-type dopants and growing the p-type epitaxial layer, the n-type dopant distribution having a second peak concentration of n-type dopants, the second peak concentration is substantially same as the first peak concentration.

In some examples, a semiconductor device includes a substrate of a first conductivity type; a first epitaxial layer of the first conductivity type on the substrate in a first region of the substrate; a second epitaxial layer of a second conductivity type on the first epitaxial layer with an interface between the first and second epitaxial layers, the second epitaxial layer having a first concentration of dopants of the second conductivity type throughout the second epitaxial layer; a first dopant distribution of second conductivity type dopants straddling across the interface, the first dopant distribution having a first peak concentration of the second conductivity type dopants greater than the first concentration; and a second dopant distribution of first conductivity type dopants straddling across the interface, the second dopant distribution having a second peak concentration of the first conductivity type dopants, the second peak concentration is substantially same as the first peak concentration.

### BRIEF DESCRIPTION OF THE DRAWINGS

FIG. 1 is a cross-sectional schematic diagram of a semiconductor device in an example of the description;

FIG. 2 is a detailed view of dopant profiles of a semiconductor device in an example of the description; and

FIG. 3A through 3F illustrate process steps of fabricating a semiconductor device in an example of the description.

### DETAILED DESCRIPTION

The present disclosure is described with reference to the attached figures. The components in the figures are not drawn to scale. Instead, emphasis is placed on clearly illustrating overall features and the principles of the present disclosure. Numerous specific details and relationships are set forth with reference to examples of the figures to provide an understanding of the disclosure. The figures and examples are not meant to limit the scope of the present disclosure to such examples, but other examples are possible by way of interchanging or modifying at least some of the described or illustrated elements. Moreover, where elements of the present disclosure can be partially or fully implemented using known components, certain portions of such components that facilitate an understanding of the present disclosure are described, and detailed descriptions of other portions of such components are omitted so as not to obscure the disclosure.

As used herein, terms such as “first” and “second” are used to arbitrarily distinguish between the elements such terms describe. Thus, these terms in the description and in the claims are not intended to indicate temporal or other prioritization of such elements. Moreover, terms such as “front,” “back,” “top,” “bottom,” “over,” “under,” “vertical,” “horizontal,” “lateral,” “down,” “up,” “upper,” “lower,” or the like, are used to refer to relative directions or positions of features in the semiconductor devices in view of the orientation shown in the figures. For example, “upper” or “uppermost” can refer to a feature positioned closer to the top of a page than other features. The terms so used are interchangeable under appropriate circumstances such that the examples of the technology described herein are, for example, capable of operation in other orientations than those illustrated or otherwise described herein. In the following discussion and in the claims, the terms “including”, “includes”, “having”, “has”, “with”, or variants thereof are intended to be inclusive in a manner similar to the term “comprising”, and thus should be interpreted to mean “including, but not limited to”. Unless otherwise stated, “about,” “approximately,” or “substantially” preceding a value means +/−10 percent of the stated value.

Various structures disclosed herein can be formed using semiconductor process techniques. Layers including a variety of materials can be formed over a substrate (e.g., a semiconductor wafer), for example, using deposition techniques (e.g., chemical vapor deposition, physical vapor deposition, atomic layer deposition, spin coating, plating), thermal process techniques (e.g., oxidation, nitridation, epitaxy), and/or other suitable techniques. Similarly, some portions of the layers can be selectively removed, for example, using etching techniques (e.g., plasma (or dry) etching, wet etching), chemical mechanical planarization, and/or other suitable techniques, some of which may be combined with photolithography steps. The conductivity (or resistivity) of the substrate (or regions of the substrate) can be controlled by doping techniques using various chemical species (which may also be referred to as dopants, dopant atoms, or the like) including, but not limited to, boron, gallium, indium, arsenic, phosphorus, or antimony. Doping may be performed during the initial formation or growth of the substrate (or an epitaxial layer grown on the substrate), by ion-implantation, or other suitable doping techniques.

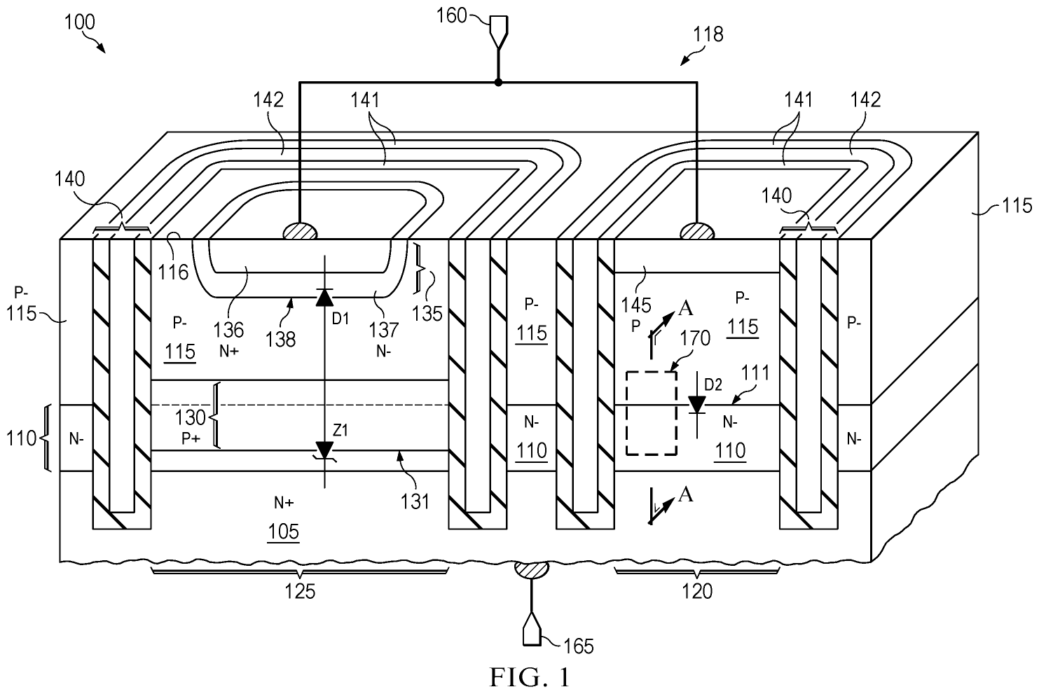

Diodes are used in a variety of ESD protection devices. Silicon-controlled rectifier (SCR) or bipolar avalanche phenomena associated with one or more p-n junctions provide low resistance current-voltage (I-V) characteristics suitable for ESD protection. For example, a bidirectional ESD protection device includes back-to-back diodes (e.g., D1-Z1 diodes with a common anode as shown in FIG. 1) combined with another diode (e.g., a D2 diode as shown in FIG. 1). As described in more detail herein, the D2 diode may be configured to have relatively low capacitance by having its p-n junction formed at an interface between a lightly doped p-type layer (e.g., p-type epitaxial layer 115) and a lightly doped n-type layer (e.g., n-type epitaxial layer 110) so as to reduce parasitic capacitance of the bidirectional ESD protection device.

In some examples, certain regions of the lightly doped n-type layer may be doped (e.g., implanted) to include relatively high concentration of dopants (e.g., p-type dopants, such as boron) before forming the lightly doped p-type layer on the lightly doped n-type layer. When the lightly doped p-type layer is formed (e.g., epitaxially grown) on the lightly doped n-type layer, the dopants (e.g., the implanted boron) present in the lightly doped n-type layer may outgas from the lightly doped n-type layer to the process chamber, and then subsequently deposit in other regions of the lightly doped n-type layer. This phenomenon may be referred to as “auto-doping.”

As a result of having unintended dopants incorporated at the interface (e.g., the p-n junction of D2 diode) during at least an initial phase of forming the lightly doped p-type layer, the dopant concentration (e.g., boron concentration) may increase at or proximate to the interface between the lightly doped p-type layer and the lightly doped n-type layer. Such increase in dopant concentration leads to increase in the capacitance (e.g., the junction capacitance) of the D2 diode because the increase in dopant concentration reduces a width of a depletion layer formed across the interface (which may be referred to as a metallurgical junction of the p-n junction). In some examples, the auto-doping may render the junction capacitance to increase to two times (2×) or more of the expected capacitance absent the auto-doping effect. In some examples, the process temperature forming the lightly doped p-type layer may be lowered to reduce out-gassing such that auto-doping can be reduced. Although such reduction of the process temperature may facilitate achieving the expected capacitance of the D2 diode, other device parameters of the bidirectional ESD protection device may be degraded, such as holding voltage (V_{HOLD}), breakdown voltage (V_{BR}), among others.

The present disclosure describes methods of compensating (or reducing) the undesired effect of the auto-doping (e.g., increased capacitance) as well as semiconductor devices fabricated based on the methods. In some examples, a blanket implantation of dopants can be performed to introduce dopants at or near the surface of the lightly doped n-type layer. The implanted dopants are of the opposite conductivity type of the dopants causing the auto-doping effect. For example, n-type dopants (e.g., phosphorus, arsenic) may be implanted into the lightly doped n-type layer in view of the p-type dopants (e.g., boron) that may auto-dope the surface of the lightly doped n-type layer. In this manner, the increased boron concentration at the interface between the n-type and p-type lightly doped layers may be compensated (e.g., at least partially canceled out) by the implanted phosphorus/arsenic concentration. Accordingly, the depletion layer across the metallurgical junction may have a width consistent with the devised process conditions (e.g., dopant concentrations in the n-type and p-type lightly doped layers absent auto-doping) to provide the desired junction capacitance, thereby mitigating the undesired effect of auto-doping, such as increased junction capacitance values.

FIG. 1 is a cross-sectional schematic diagram of a semiconductor device 100 in an example of the description. The semiconductor device 100 includes an n-type substrate 105. The substrate 105 may be, for example, part of a bulk silicon wafer. A dynamic resistance of the semiconductor device 100 may be predominantly determined by the dopant density in the substrate 105 (or resistivity of the substrate 105). The n-type substrate 105 may have an average dopant density greater than 1×10¹⁸ cm⁻³. In some examples, the n-type substrate 105 can have an average dopant density exceeding 4×10¹⁹ cm⁻³.

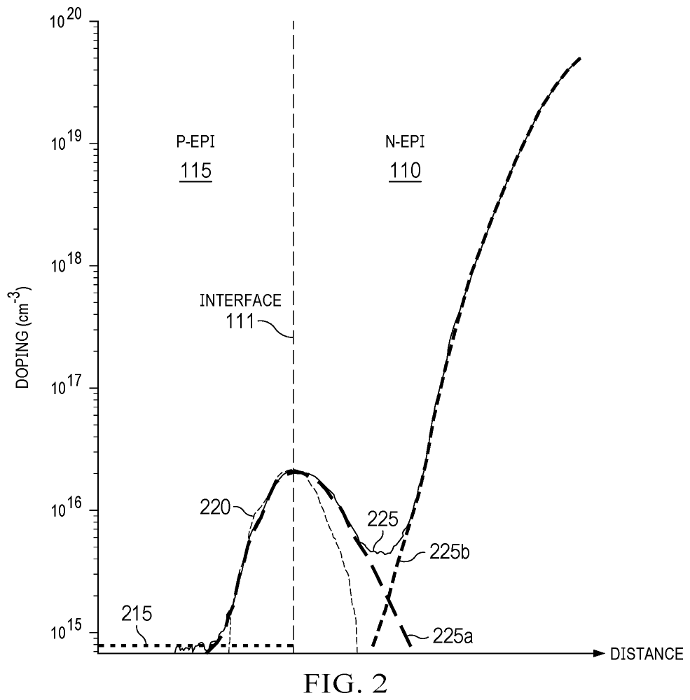

The semiconductor device 100 includes a lightly doped n-type layer 110 disposed on the substrate 105. In some examples, the n-type layer 110 may be phosphorus-doped crystalline silicon. The n-type layer 110 may be 1 micron (μm) to 10 microns thick. In some examples, the n-type layer 110 have an average dopant density less than 1×10¹⁶ cm⁻³. In some examples, the n-type layer 110 may have an average dopant density greater than 1×10¹⁶ cm⁻³ as shown in FIG. 2 (e.g., including dopants diffused from the substrate 105 and/or dopants incorporated during the n-type layer 110 formation), but less than the substrate 105. The n-type layer 110 may be an epitaxial layer formed on the substrate 105. As such, the n-type layer 110 may be referred to as an n-type epitaxial layer, n-type epi-layer, n-epi layer, or the like.

The semiconductor device 100 includes a lightly doped p-type layer 115 disposed on or over the n-type layer 110. In some examples, the p-type layer 115 may be boron-doped crystalline silicon. The p-type layer 115 may be 3 microns to 8 microns thick. In some examples, the p-type layer 115 may have an average dopant density of about 1×10¹⁵ cm⁻³ or less. In some examples, the p-type layer 115 may have an average dopant density between 1×10¹³ cm⁻³ and 1×10¹⁶ cm⁻³. The p-type layer 115 may be an epitaxial layer formed on the n-type layer 110. As such, the p-type layer 115 may be referred to as a p-type epitaxial layer, p-type epi-layer, p-epi layer, or the like. The p-type layer 115 has a surface (e.g., a top surface) 116.

The semiconductor device 100 includes a first region 120 where a diode is located. As denoted in FIG. 1, the diode in the first region 120 may be referred to as D2 diode that includes a p-n junction formed at an interface 111 between the n-epi layer 110 and the p-epi layer 115. The semiconductor device 100 also includes a second region 125 where two diodes are located, which are connected back-to-back in a series configuration. As denoted in FIG. 1, the diodes in the second region 125 may be referred to as D1 diode and Z1 diode. The D1 diode includes a p-n junction formed at an interface 138 between the n-type region 135 and the p-type epi-layer 115. The Z1 diode includes a p-n junction formed at an interface 131 between the p-type buried layer 130 and the n-type layer 110. The p-type epi-layer 115 under the n-type region 135 and the p-type buried layer 130 form a common anode for the D1 and Z1 diodes.

The semiconductor device 100 includes isolation structures 140 laterally surrounding the first region 120 for the D2 diode and the second region 125 for the D1-Z1 diodes. In some examples, the isolation structures 140 may be deep trench isolation structures with dielectric liners 141 and a trench fill 142. In some examples, the trench fill may be polycrystalline silicon (which may also be referred to as polysilicon) on the dielectric liners 141, as depicted in FIG. 1.

The p-type buried layer 130 is located in the second region 125 (absent in the first region 120), extending from the p-type layer 115 into the n-type layer 110 without penetrating through the n-type layer 110. The original surface of the n-type layer 110 in the second region 125 is depicted in FIG. 1 with dashed lines within the p-type buried layer 130. The p-type buried layer 130 may have a peak dopant density greater than 1×10¹⁷ cm⁻³. The p-type buried layer 130 extends laterally across the second region 125 as depicted in FIG. 1.

The n-type doped region 135 is located in the p-type layer 115 of the second region 125, which extends to the top surface 116 of the p-type layer 115. The n-type doped region 135 may have an average dopant density of, for example, 1×10¹⁶ cm⁻³ 3×10¹⁹ cm⁻³. The n-type region 135 may include an inner portion 136 and an outer portion 137 that has less dopant density than the inner portion 136. The lighter-doped outer portion 137 contacts the p-type epi layer 115 and a heavier-doped inner portion 136 is within the lighter-doped outer portion 137. The lighter-doped outer portion 137 may have an average dopant density of, for example, 1×10¹⁶ cm⁻³ to 1×10¹⁷ cm⁻³. The heavier-doped inner portion 136 may have an average dopant density of, for example, 1×10¹⁷ cm⁻³ to 5×10¹⁹ cm⁻³.

A p-type doped region 145 is disposed in the p-type epi-layer 115 of the first region 120, which extends to the top surface 116 of the p-type epi-layer 115. The p-type doped region 145 extends across the first region 120 as depicted in FIG. 1. The p-type region 145 may have an average dopant density of at least 1×10¹⁷ cm⁻³ and may provide a desired low resistance contact for the D2 diode. The substrate 105 may form a common cathode for the D2 diode and the Z1 diode.

A first terminal 160 of the semiconductor device 100 is electrically connected to the n-type region 135 of the DI diode and to the p-type region 145 of the D2 diode as shown schematically in FIG. 1. The first terminal 160 may be integrated into the semiconductor device 100, or may be a separate external connection, such as a wire bond or a bump bond. A second terminal 165 is electrically connected to the substrate 105 as shown schematically in FIG. 1, which may be solder or an electrically conductive die attach material in some examples. During operation of the semiconductor device 100, a voltage excursion which is positive on the first terminal 160 relative to the second terminal 165 forward biases the D2 diode and is thus shunted through the D2 diode. A voltage excursion which is negative on the first terminal 160 relative to the second terminal 165 forward biases the D1 diode and causes breakdown in the Z1 diode, and is thus shunted through the D1-Z1 diodes.

As described herein, the semiconductor device 100 includes three different p-n junctions, namely the D1 diode with a first p-n junction formed at the interface 138, the Z1 diode with a second p-n junction formed at the interface 131, and the D2 diode with a third p-n junction formed at the interface 111, respectively. The first junction at the interface 138 may be configured to provide relatively low capacitance for the semiconductor device 100 in view of the lighter-doped outer portion 137 in contact with the p-type layer 115. The second junction at the interface 131 may be configured to provide a desired breakdown voltage for the semiconductor device 100 in view of the p-type buried layer 130 in contact with the n-type layer 110. The third p-n junction at the interface 111 may be configured to provide relatively low capacitance for the semiconductor device 100 in view of the lightly doped p-type layer 115 in contact with the n-type layer 110.

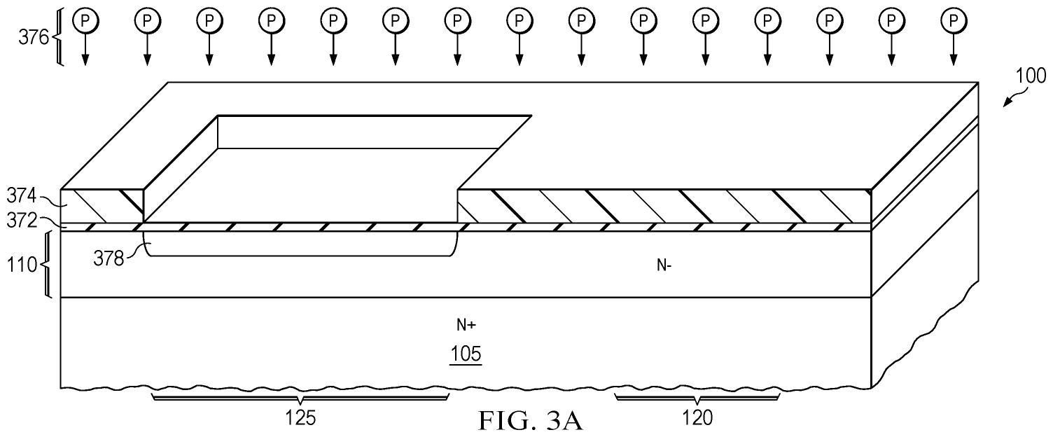

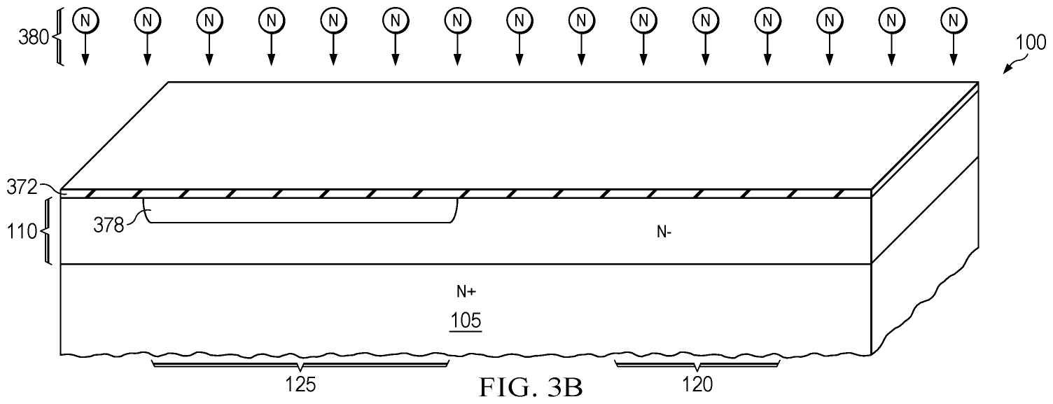

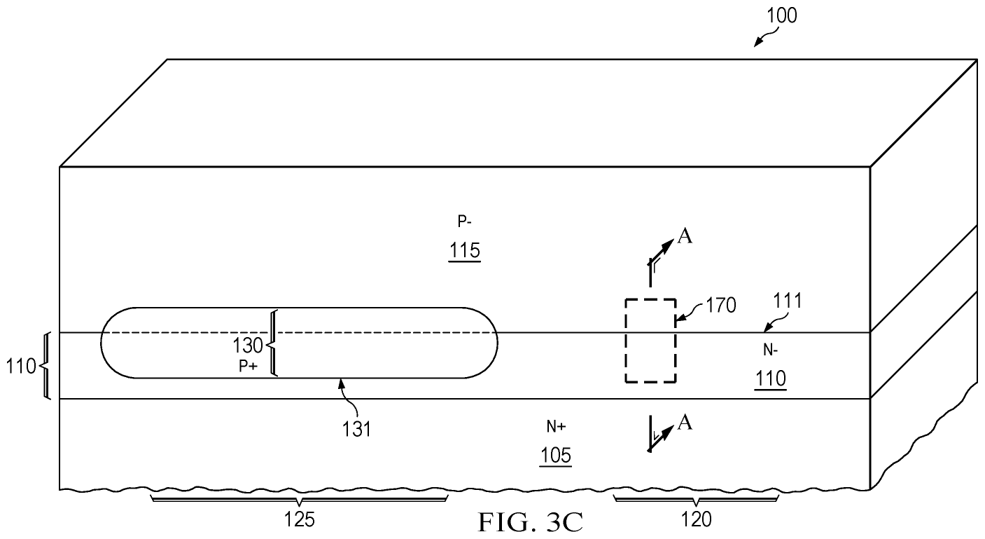

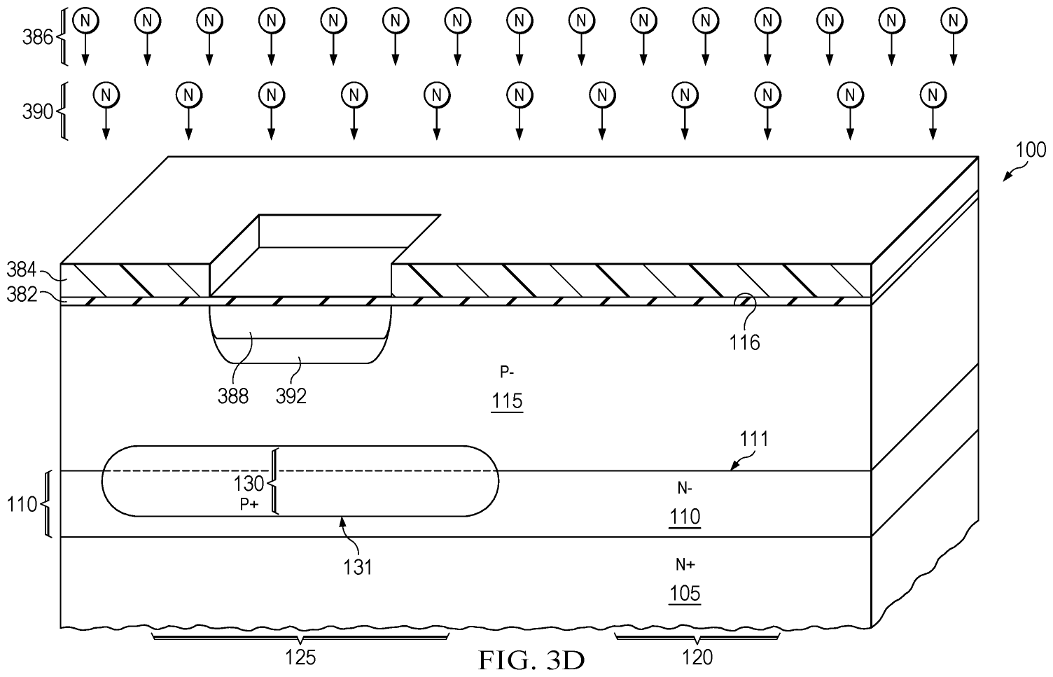

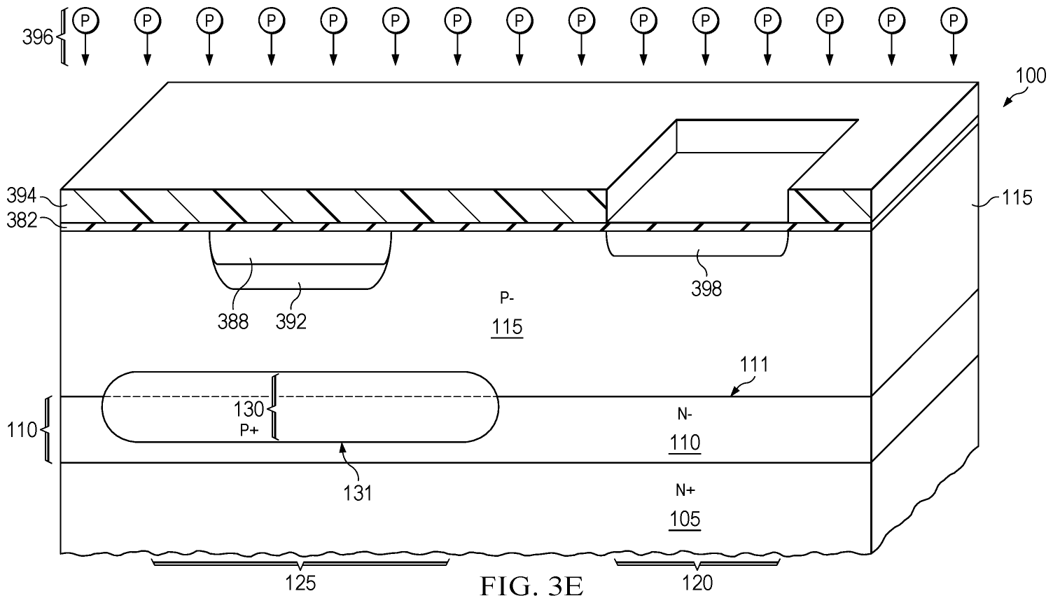

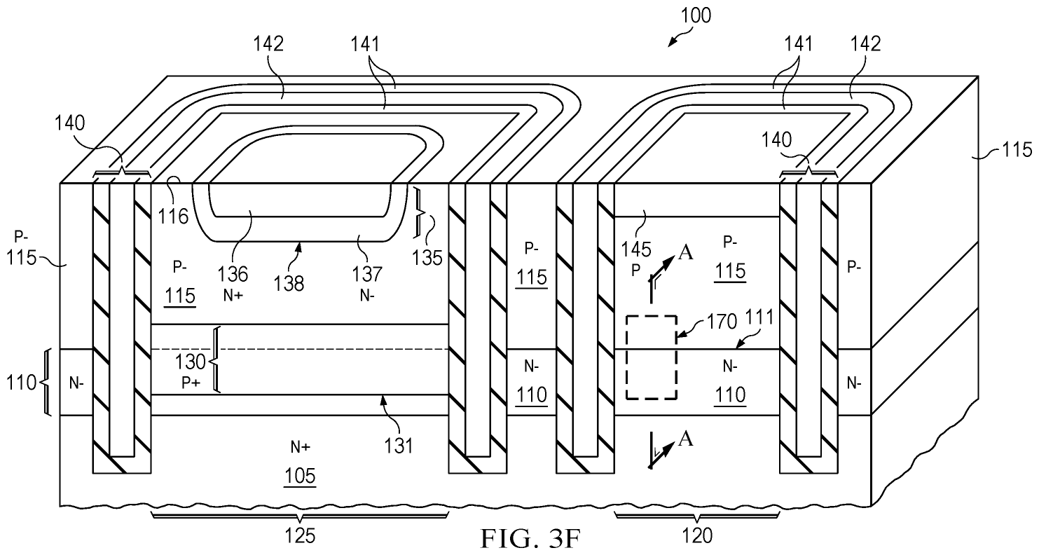

The capacitance of the D2 diode is determined by the dopant densities of the n-type layer 110 and the p-type layer 115 at the third p-n junction at the interface 111. In some examples, the capacitance of the D2 diode may be comparable to the first p-n junction at the interface 138. In some examples, as described in more detail with reference to FIGS. 3A through 3C, the dopants present in the p-type buried layer 130 may outgas during the epitaxial process step forming the p-type layer 115 (e.g., to the epi-process chamber), and then subsequently deposit on the n-type layer 110 such that the dopant density at or proximate the interface 111 is increased-e.g., “auto-doping” the p-type layer 115 and the n-type layer 110 at or proximate the interface 111. The auto- doping may adversely increase the capacitance of the D2 diode as described herein.

The semiconductor device 100 includes dopants disposed at or near the interface 111—e.g., to mitigate the auto-doping effect. The dopants may be implanted dopants, and of opposite conductivity type of the dopants causing the auto-doping effect. For example, n-type dopants (e.g., phosphorus, arsenic, antimony) may be implanted into the n-type layer 110 in view of the p-type dopants (e.g., boron from the p-type buried layer 130) that may auto-dope the p-type layer 115 and the n-type layer 110 at or proximate the interface 111. In this manner, the increased boron concentration at or proximate the interface 111 between the n-type layer 110 and the p-type layer 115 may be compensated (e.g., at least partially canceled out) by the implanted phosphorus (or arsenic/antimony) concentration. Accordingly, the depletion layer across the metallurgical junction may have a width consistent with the process conditions (e.g., dopant concentrations in the n-type and p-type lightly doped layers 110, 115) that are devised to provide a desired capacitance of the D2 diode. In this manner, the undesired increase in the junction capacitance due to the auto-doping can be mitigated. FIG. 1 includes a boxed area 170 including the interface 111 between the n-type layer 110 and the p-type layer 115, and further details of the boxed area 170 are described with reference to FIG. 2.

FIG. 2 is a detailed view of dopant profiles of a semiconductor device (e.g., the semiconductor device 100) in an example of the description. The dopant profiles are taken across a line A-A that extends across the boxed area 170 including portions of the p-epi layer 115 and the n-epi layer 110, which includes the interface 111as shown in FIG. 1. The substrate 105 may have n-type dopants with a concentration greater than 1×10¹⁹ cm⁻³ as described above. Also, the n-epi layer 110 may have n-type dopants with an average concentration greater than 1×10¹⁶ cm⁻³ as shown in FIG. 2. The p-epi layer 115 may have p-type dopants with a concentration of about 8×10¹⁴ cm⁻³ as shown in the example implementation of FIG. 2. The dopant concentration profile 215 of the p-epi layer 115 shows that the p-type dopants are distributed substantially uniform throughout the p-epi layer 115—e.g., the dopant concentration profile 215 being substantially flat as shown in FIG. 2.

FIG. 2 also shows a dopant concentration profile 220 of p-type dopants. The p-type dopants of the concentration profile 220 may be a result of the auto-doping—e.g., boron present in the p-type buried layer 130 in the second region 125 outgassed and deposited in the first region 120 as described with reference to FIG. 3C. In other words, the p-type dopants of the concentration profile 220 originate from the p-type buried layer 130 (or the region 378 including the p-type dopants as described with reference to FIG. 3A) in the second region 125. The p-type dopant distribution of the concentration profile 220 may straddle (spread) across the interface 111. Moreover, the p-type dopant distribution has a peak concentration of p-type dopants greater than the concentration of the p-epi layer 115. In some examples, the peak concentration of p-type dopants may be at least five (5) times greater than the p-epi layer 115. In some examples, the peak concentration of the profile 220 is located at the interface 111.

FIG. 2 also shows a dopant concentration profile 225 of n-type dopants (e.g., phosphorus). The dopant concentration profile 225 may include the n-type dopants from multiple origins. The dopant concentration profile 225 may include the n-type dopants diffused from the substrate 105 as depicted as phosphorus concentration profile 225b. Moreover, the dopant concentration profile 225 may include the n-type dopants implanted to the n-epi layer 110 as depicted as phosphorus concentration profile 225a. The implantation may be carried out prior to forming (e.g., epitaxially growing) the p-epi layer 115 to compensate the auto-doping effect-e.g., due to the p-type dopants of the concentration profile 220. In the example implementation shown in FIG. 2, the n-type dopants of the concentration profile 225a correspond to phosphorus implanted at a dose of 2×10¹² cm⁻² at 130 keV. In other examples, arsenic may be implanted at a dose of 3×10¹² cm⁻² at 150 keV.

Based on various process conditions, implant conditions for the concentration profile 225a may vary, such as the p-type dopant concentration in the region 378, the epitaxial growth process conditions for the p-epi layer 115, species to be implanted to form the desired dopant concentration profile 225a to mitigate the auto-doping effect, among others. In some examples, phosphorus can be implanted with a dose approximately between 1×10¹¹ cm⁻² and 1×10¹³ cm⁻² at an implant energy approximately between 30 keV and 200 keV. Similarly, in some examples, arsenic can be implanted with a dose approximately between 1×10¹¹ cm⁻² and 1×10¹³ cm⁻² at an implant energy approximately between 50 keV and 300 keV.

The n-type dopant distribution of the concentration profile 225a may spread (straddles) across the interface 111-e.g., as a result of the implanted n-type dopants being incorporated into the p-epi layer 115 during the p-epi layer formation. The n-type dopant distribution of the concentration profile 225a may straddle across the interface 111 with a peak concentration of the n-type dopants substantially same as the peak concentration of the p-type dopant distribution of the concentration profile 220. In this manner, the p-type dopants incorporated into the first region 120 due to auto-doping can be compensated by the n-type dopants of the concentration profile 225a. In some examples, the peak concentration of the concentration profile 225a is located at the interface 111. Moreover, at or proximate the interface 111, the peak concentration of the concentration profile 225a may be greater than the dopant concentration of the n-epi layer 110—e.g., the n-type dopant concentration present at or near the interface 111 absent the n-type dopants of the concentration profile 225a.

FIG. 3A through FIG. 3F illustrate process steps of fabricating a semiconductor device (e.g., the semiconductor device 100) in an example of the description. FIG. 3A illustrates that the n-type layer 110 is formed on the substrate 105, for example, using an epitaxial process. The n-type dopants present in the substrate 105, such as phosphorus (or possibly arsenic or antimony), may diffuse into the n-type layer 110 during the epitaxial process as shown in FIG. 2 (e.g., the dopant concentration profile 225b). Additional n-type dopants, such as phosphorus and/or arsenic may be introduced into the n-type layer 110 during the epitaxial process (e.g., in-situ doped n-type layer 110).

FIG. 3A also illustrates that a layer of pad oxide 372 may be formed on the n-type layer 110. The layer of pad oxide 372 may be formed by thermal oxidation, and may be 5 nanometers to 50 nanometers thick. The layer of pad oxide 372 protects the surface of the n-type layer 110 during subsequent processing. A first implant mask 374 is formed over the layer of pad oxide 372 which exposes the second area 125 to form the p-type buried layer 130. The first implant mask 374 covers the first area 120 for the D2 diode. The first implant mask 374 may include photoresist formed by a photolithographic process and may include hard mask material such as silicon dioxide or silicon nitride. P-type dopants 376 such as boron, and possibly gallium or indium, are implanted into the n-type layer 110 in the second area 125 uncovered by the first implant mask 374 to form a region 378 implanted with the p-type dopants 376 in the n-type layer 110 underneath the layer of pad oxide 372. The layer of pad oxide 372 may reduce channeling of the implanted p-type dopants 376, which may advantageously provide a more reproducible dopant distribution in the p-type buried layer 130 and thus provide a more consistent breakdown voltage for the Z1 diode. The p-type dopants 376 may have a dose of 3×10¹³ cm⁻² or greater to provide the peak dopant density greater than 1×10¹⁷ cm⁻³.

FIG. 3B illustrates that the first implant mask 374 is removed after the p-type dopants 376 are implanted. FIG. 3B also illustrates that n-type dopants 380 such as phosphorus or arsenic (or antimony) are implanted into the n-type layer 110 after the first implant mask 374 is removed. The n-type dopants 380 correspond to the n-type dopants of the dopant concentration profile 225a described with reference to FIG. 2 (without subsequent diffusion of the implanted n-type dopants). In some examples, implanting the n-type dopants 380 may include implanting phosphorus at a dose of 3×10¹² cm⁻² at 80 keV or implanting arsenic at a dose of 3×10¹² cm⁻² at 150 keV. As depicted in FIG. 3B, the implant process may be a blanket implant process without an implant mask. In view of the dose of the p-type dopants 376 in the region 378 (corresponding to the p-type buried layer 130) being approximately ten (10) times greater than the dose of the n-type dopants 380, the n-type dopants 380 implanted in the region 378 may not adversely impact desired electrical characteristics of the p-type buried layer 130. In some examples, an implant mask may be formed to open the first region 120 (while covering the second region 125) prior to implanting the n-type dopants 380.

An anneal process may be performed to activate the implanted p-type dopants 376 in the implanted region 378 as well as the implanted n-type dopants 380. The anneal process may be a rapid thermal process, for one example, which heats the substrate 105 (and the n-type layer 110) to a temperature of 1000° C. to 1050° C. for 20 seconds to 60 seconds, or may be a furnace anneal, for another example, which heats the substrate 105 and n-type layer 110 to a temperature of 850° C. to 950° C. for 30 minutes to 120 minutes. The layer of pad oxide 372 is subsequently removed, for example by a dilute aqueous buffered solution of hydrofluoric acid.

FIG. 3C illustrates that the p-type layer 115 is formed on the n-type layer 110—e.g., using an epitaxial process. P-type dopants, such as boron may be introduced into the p-type layer 115 during the epitaxial process (e.g., in-situ doped) to provide an average dopant density of about 1×10¹⁵ cm⁻³ or less. During the epitaxial process to form the p-type layer 115, the p-type dopants of the implanted region 378 diffuse upward into the p-type layer 115 and downward to extend into the n-type layer 110, to form the p-type buried layer 130. The p-type dopants of the p-type buried layer 130 counter dope a portion of the n-type layer 110 in the second area 125. The original surface of the n-type layer 110 is depicted with a dashed line in the p-type buried layer 130 in FIG. 3C through FIG. 3F.

FIG. 3C also illustrates the boxed area 170 that includes the interface 111, portions of the p-epi layer 115 and the n-epi layer 110. Dopant profiles across the line A-A through the boxed area 170 may be substantially the same as the dopant profiles described in detail with reference to FIG. 2. In other words, although the dopant profiles of the boxed area 170 right after completing the epitaxial process growing the p-type layer 115 may be slightly different than the dopant profiles described with reference to FIG. 2 (e.g., due to additional thermal cycles that the dopants experience during subsequent process steps), overall features of the dopant profiles described with reference to FIG. 2 are applicable to the dopant profiles present across the boxed area 170 after completing the epitaxial process growing the p-type layer 115.

FIG. 3D illustrates that another layer of pad oxide 382 may be formed over the top surface 116 of the p-type layer 115 to protect the p-type layer 115 during subsequent processing. The layer of pad oxide 382 may be formed similarly to the layer of pad oxide 372 described with reference to FIG. 3A. A second implant mask 384 is formed over the second layer of pad oxide 382 to expose an area in the second region 125 to form the n-type region 135 described with reference to FIG. 1. The second implant mask 384 covers the first region 120 for the D2 diode. The second implant mask 384 may include photoresist formed by a photolithographic process.

A first set of n-type dopants 386 (e.g., phosphorus, arsenic, or antimony) is implanted into the p-type layer 115 in the area exposed by the second implant mask 384 to form a first n-type implanted region 388 in the p-type layer 115 immediately below the pad oxide 382. The first set of n-type dopants 386 may have a total dose of, for example, 1×10¹⁵ cm⁻² to 1×10¹⁶ cm⁻² and an energy to provide an average depth of 50 nanometers to 200 nanometers, to provide the n-type dopants for the heavier-doped inner portion 136 of the n-type region 135 described with reference to FIG. 1. A second set of n-type dopants 390 (e.g., phosphorus, arsenic, or antimony) is implanted into the p-type layer 115 in the area exposed by the second implant mask 384 to form a second n-type implanted region 392 in the p-type layer 115 immediately below the first n-type implanted region 388. The second set of n-type dopants 390 may have a total dose of, for example, 1×10¹³ cm⁻² to 1×10¹⁴ cm⁻² and an energy of, for example, 250 keV to 600 keV for the phosphorus, to provide the n-type dopants for the lighter-doped inner portion 137 of the n-type region 135 described with reference to FIG. 1. Subsequently, the second implant mask 384 is removed.

Referring to FIG. 3E, a third implant mask 394 is formed over the layer of pad oxide 382 to expose an area in the first region 120 for the p-type region 145 of FIG. 1. The third implant mask 394 covers the second region 125 for the D1-Z1 diodes. The third implant mask 394 may be formed similarly to the second implant mask 384 of FIG. 3D. A set of p-type dopants 396 is implanted into the p-type layer 115 in the area exposed by the third implant mask 394 to form a p-type implanted region 398 in the p-type layer 115 immediately below the pad oxide 382. The p-type dopants 396 may have a total dose of, for example, 1×10¹⁵ cm⁻² to 1×10¹⁶ cm⁻². Subsequently, the third implant mask 394 is removed. In some examples, a thermal cycle may be carried out to activate the dopants in the implanted regions 388, 392, and 398, respectively.

Referring to FIG. 3F, the isolation structures 140 are formed through the p-type layer 115 and the n-type layer 110, extending into the substrate 105. The isolation structures 140 laterally surround the first region 120 for the D2 diode and the second region 125 for the D1-Z1 diodes, respectively. The isolation structures 140 may be formed by etching isolation trenches through the p-type layer 115, the n-type layer 110, and into the substrate 105. Subsequently, a dielectric liner 141 is formed on the trenches. In some examples, the dielectric liner 141 includes a layer of thermal oxide grown on sidewalls and bottoms of the isolation trenches.

Subsequently, a trench fill 142 is formed on the dielectric liner 141. In some examples, the trench fill 142 includes a layer of polysilicon is formed on the dielectric liner 141, extending into the isolation trenches. In some examples, the polysilicon trench fill 142 may be referred to as field plates. The polysilicon (and the dielectric liner 141 in some cases) may be removed from over the top surface 116 of the p-type layer 115 leaving the isolation structures 140—e.g., by an etch-back process and/or a chemical mechanical polish (CMP) process. In some examples, a thermal cycle associated with forming the dielectric liner 141 activates and diffuses the implanted n-type dopants in the first n-type implanted region 388 and the second n-type implanted region 392 of FIG. 3E to form the heavier-doped inner portion 136 and the lighter-doped inner portion 137, respectively, of the n-type region 135. Also, the thermal cycle activates and diffuses the implanted p-type dopants in the p-type implanted region 398 of FIG. 3E to form the p-type region 145. An optional thermal drive process such as a furnace anneal may be performed to further diffuse the implanted n-type dopants and the implanted p-type dopants, either before or after formation of the isolation structures 140.

Formation of the semiconductor device 100 continues with formation of electrical connections to the substrate 105, the n-type region 135 and the p-type region 145 to provide the structure of FIG. 1.

Various example of the description have been described above by way of example only and not limitation. Numerous changes to the examples can be made in accordance with the description without departing from the spirit or scope of the description. For example, although examples described above with reference to FIGS. 1 through 3F include various semiconductor layers (e.g., n-epi layer, p-epi layer) and doped regions (e.g., n-doped region, p-doped region) based on an n-type substrate, the description is not limited thereto. In some examples, semiconductor devices of the description can be fabricated based on a p-type substrate in conjunctions with the various doped region being opposite polarities-e.g., interchanging acceptor (p-type) and donor (n-type) dopant atoms. In addition, while in the illustrated embodiments various features or components have been shown as having particular arrangements or configurations, other arrangements and configurations are possible. Moreover, aspects of the present technology described in the context of example embodiments may be combined or eliminated in other embodiments. Thus, the breadth and scope of the description is not limited by any of the above described embodiments.

What is claimed is:

1. A semiconductor device, comprising:
an n-type substrate;
an n-type epitaxial layer on the n-type substrate in a first region of the n-type substrate;
a p-type epitaxial layer on the n-type epitaxial layer with an interface between the n-type and p-type epitaxial layers, the p-type epitaxial layer having a first concentration of p-type dopants throughout the p-type epitaxial layer;
a p-type dopant distribution straddling across the interface, the p-type dopant distribution having a first peak concentration of p-type dopants greater than the first concentration; and
an n-type dopant distribution straddling across the interface, the n-type dopant distribution having a second peak concentration of n-type dopants, the second peak concentration is substantially same as the first peak concentration.

2. The semiconductor device of claim 1, wherein:
the first peak concentration is located at the interface; and
the second peak concentration is located at the interface.

3. The semiconductor device of claim 1, wherein the first peak concentration is at least five (5) times greater than the first concentration.

4. The semiconductor device of claim 1, wherein:
the n-type epitaxial layer includes a second concentration of n-type dopants at the interface; and
the second peak concentration is greater than the second concentration.

5. The semiconductor device of claim 1, wherein the interface corresponds to a metallurgical junction of a p-n diode formed by the n-type and p-type epitaxial layers.

6. The semiconductor device of claim 1, wherein the p-type epitaxial layer includes a p-type doped region proximate a surface of the p-type epitaxial layer.

7. The semiconductor device of claim 1, wherein the p-type epitaxial layer is a first portion of the p-type epitaxial layer corresponding to the first region of the n-type substrate, the semiconductor device further comprising:
a p-type buried layer extended partially into the n-type epitaxial layer in a second region of the n-type substrate; and
a second portion of the p-type epitaxial layer on the p-type buried layer, wherein the second portion of the p-type epitaxial layer includes an n-type doped region proximate a surface of the second portion of the p-type epitaxial layer.

8. The semiconductor device of claim 7, wherein:
the n-type doped region and the second portion of the p-type epitaxial layer forms a first p-n diode; and
the p-type buried layer and the n-type epitaxial layer forms a second p-n diode, wherein the second portion of the p-type epitaxial layer and the p-type buried layer forms a common anode for the first and second p-n diodes.

9. The semiconductor device of claim 8, wherein:
the n-type epitaxial layer and the first portion of the p-type epitaxial layer forms a third p-n diode; and
the n-type substrate forms a common cathode for the second and third p-n diodes.

10. A method, comprising:
growing an n-type epitaxial layer on an n-type substrate;
implanting p-type dopants in a second region of the n-type epitaxial layer;
implanting n-type dopants in a first region of the n-type epitaxial layer different than the second region; and
growing a p-type epitaxial layer over the n-type substrate such that an interface forms between the n-type and p-type epitaxial layers in the first region, wherein:
the p-type epitaxial layer in the first region includes a first concentration of p-type dopants throughout the p-type epitaxial layer;
a p-type dopant distribution forms across the interface as a result of growing the p-type epitaxial layer, the p-type dopant distribution having a first peak concentration of p-type dopants greater than the first concentration; and
an n-type dopant distribution forms across the interface as a result of implanting n-type dopants and growing the p-type epitaxial layer, the n-type dopant distribution having a second peak concentration of n-type dopants, the second peak concentration is substantially same as the first peak concentration.

11. The method of claim 10, wherein:
the first peak concentration is located at the interface; and
the second peak concentration is located at the interface.

12. The method of claim 10, wherein the first peak concentration is at least five (5) times greater than the first concentration.

13. The method of claim 10, wherein:
the n-type epitaxial layer includes a second concentration of n-type dopants at the interface; and
the second peak concentration is greater than the second concentration.

14. The method of claim 10, wherein the interface corresponds to a metallurgical junction of a p-n diode formed by the n-type and p-type epitaxial layers in the first region.

15. The method of claim 10, wherein the p-type dopant distribution formed across the interface originates from the p-type dopants implanted in the second region of the n-type epitaxial layer.

16. A semiconductor device, comprising:
a substrate of a first conductivity type;
a first epitaxial layer of the first conductivity type on the substrate in a first region of the substrate;
a second epitaxial layer of a second conductivity type on the first epitaxial layer with an interface between the first and second epitaxial layers, the second epitaxial layer having a first concentration of dopants of the second conductivity type throughout the second epitaxial layer;
a first dopant distribution of second conductivity type dopants straddling across the interface, the first dopant distribution having a first peak concentration of the second conductivity type dopants greater than the first concentration; and
a second dopant distribution of first conductivity type dopants straddling across the interface, the second dopant distribution having a second peak concentration of the first conductivity type dopants, the second peak concentration is substantially same as the first peak concentration.

17. The semiconductor device of claim 16, wherein:
the first peak concentration is located at the interface; and
the second peak concentration is located at the interface.

18. The semiconductor device of claim 16, wherein the first peak concentration is at least five (5) times greater than the first concentration.

19. The semiconductor device of claim 16, wherein:
the first epitaxial layer includes a second concentration of the first conductivity type dopants at the interface; and
the second peak concentration is greater than the second concentration.

20. The semiconductor device of claim 16, wherein the interface corresponds to a metallurgical junction of a diode formed by the first and second epitaxial layers.
